(19) United States
(12) Patent Application Publication
(10) Pub. No.: US 2026/0275018 A1
(43) Pub. Date: Sep. 17, 2026

(54) PHOTOCURABLE COMPOSITION FOR FORMING AN IMPRINT LITHOGRAPHY TEMPLATE

(71) Applicant: CANON KABUSHIKI KAISHA, Tokyo (JP)

(72) Inventors: Fen WAN, Austin, TX (US); Weijun LIU, Cedar Park, TX (US); Caroline M. MCCUISTION, Austin, TX (US)

(21) Appl. No.: 19/074,752

(22) Filed: Mar. 10, 2025

(51) Int. Cl. C08F 230/08; C08F 2/50; C08F 222/10; G03F 7/00

(52) U.S. Cl. CPC C08F 230/085; C08F 2/50; C08F 222/1025; C08F 222/103; G03F 7/002

(57) ABSTRACT

A photocurable composition can comprise a polymerizable material and at least one photoinitiator, wherein the polymerizable material comprises at least one first monomer being a silicon-containing monomer, and at least one second monomer being essentially free of silicon and containing at least 30 wt % of a multi-functional monomer. The at least one first monomer can have a structure of formula (1):

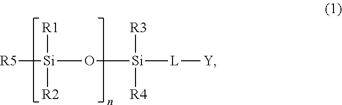

wherein: R1, R2, R3, and R4 are independently selected from —O—Si(CH₃)₃, alkyl, aryl, or alkylaryl; L is C₁-C₆-alkyl, or aryl, or alkylaryl; R5 is -L-Y, or Y, or —O—Si(CH₃)₃, or alkyl, or aryl, or alkylaryl; Y is acrylate, or methacrylate, or vinyl; and n is 0-4. The amount of silicon can be at least 5 wt % and not greater than 14 wt % based on the total weight of the polymerizable material. The photocurable composition can be adapted for forming soft patterned molds usable for NIL processing.

### FIELD OF THE DISCLOSURE

The present disclosure relates to a photocurable composition, particularly to a photocurable composition for forming an imprint lithography template.

### BACKGROUND

Nanoimprint lithography (NIL) involves the use of patterned templates having a high sub-10 nm resolution. Typically, an expensive mother mask or mother template is used to form patterned daughter templates, and the daughter templates are employed to transfer a desired pattern unto a wafer. A daughter template (herein also called imprint lithography template) can have a two-layer structure: a quartz backing and a patterned polymeric layer placed on top of the quartz backing. The requirements for photocurable compositions to make the patterned layer are complex, involving a balance between low viscosity, good spreading behavior, fast curing, good releasability of the mother-template after curing, and high mechanical strength after the curing.

There exists a need for improved photocurable compositions which meet the desired key parameters for forming soft patterned molds usable for NIL processing such that lowered costs of ownership (CoO) can be obtained, and products having a high thermal stability and mechanical strength after the curing.

### SUMMARY

In one embodiment, a photocurable composition can comprise a polymerizable material and at least one photoinitiator, wherein the polymerizable material comprises at least one first monomer and at least one second monomer, the at least one first monomer being a silicon-containing monomer and the at least one second monomer being essentially free of silicon; the at least on first monomer has a structure of formula (1):

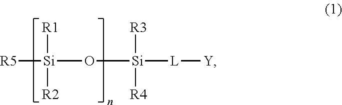

wherein: R1, R2, R3, and R4 are independently selected from —O—Si(CH₃)₃, alkyl, aryl, or alkylaryl; L is C₁-C₅-alkyl, or aryl, or alkylaryl; R5 is -L-Y, or Y, or —O—Si(CH₃)₃, or alkyl, or aryl, or alkylaryl; Y is acrylate, or methacrylate, or vinyl; n is 0-4; an amount of silicon is at least 5 wt % and not greater than 14 wt % based on the total weight of the polymerizable material; and the at least one second monomer comprises at least one multi-functional monomer, wherein in an amount of at least one multi-functional monomer of the second monomer is at least 30 wt % based on the total weight of the polymerizable material.

In one aspect of the photocurable composition, wherein the amount of the polymerizable material can be at least 80 wt % based on the total weight of the photocurable composition.

In another aspect of the photocurable composition, the silicon-containing monomer can comprise at least one acrylate group.

In a further aspect, the amount of the silicon-containing monomer can be at least 20 wt % based on the total weight of the polymerizable material. In a particular aspect, the amount of silicon-containing monomer can be at least 40 wt % based on the total weight of the polymerizable material.

In another aspect, the silicon-containing monomer can have a structure selected from:

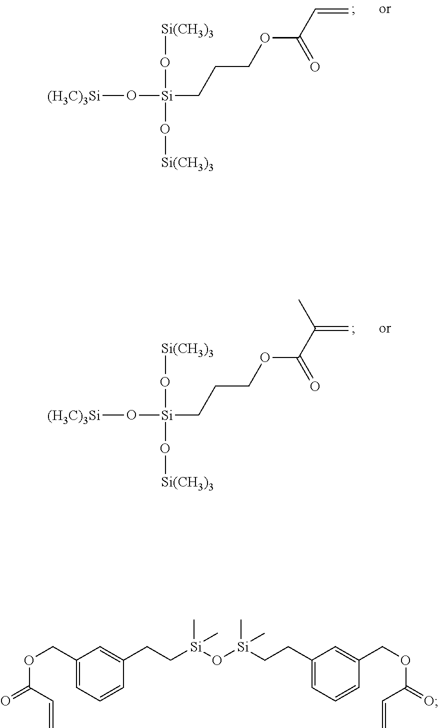

or any combination thereof.

In a certain aspect of the photocurable composition, the amount of the multi-functional monomer can be at least 45 wt % based on the total weight of the polymerizable material.

In one embodiment, the at least one second monomer of the polymerizable material can include a di-functional acrylate monomer, a tri-functional acrylate monomer, or a combination thereof. In certain aspects, the at least one second monomer can comprise trimethylolpropane triacrylate, tricyclodecane dimethanol diacrylate, meta-xylene diacrylate, or any combination thereof.

In a particular aspect of the photocurable composition, the at least one second monomer can consist essentially of a tri-functional acrylate monomer.

In a certain particular aspect, the polymerizable material can consist essentially of the at least one first monomer and the at least one second monomer, the at least one second monomer can be a multi-functional acrylate monomer, and a weight-percent ratio between the at least one first monomer to the at least one second monomer ranges from 2.5:1 to 1:4.

In another aspect, the photocurable composition can be essentially free of fluorine.

In one aspect, the viscosity of the photocurable composition at a temperature of 25° C. can be not greater than 30 mPa·s.

In yet another aspect of the photocurable composition, the molecular weight of the silicon containing monomer can be at least 250 g/mol and not greater than 800 g/mol.

In a further aspect of the photocurable composition, the vapor pressure of the silicon containing monomer at 25° C. can be not greater 0.01 Torr.

In one embodiment, an imprint lithography template can comprise a backing layer and a patterned layer overlying the backing layer, wherein the patterned layer can be formed from the photocurable composition of claim 1.

In one aspect of the imprint lithography template, the patterned layer can have a reduced modulus of at least 0.5 GPa.

In another aspect of the imprint lithography template, the patterned layer can have a hardness of at least 0.05 GPa.

In a further aspect of the imprint lithography template, the water contact angle of the patterned layer can be at least 70°.

In another embodiment, a method an imprint lithography template can comprise: applying a layer of a photocurable composition on a backing layer, wherein the photocurable composition comprises a polymerizable material and at least one photoinitiator, the polymerizable material comprises at least one first monomer and at least one second monomer, the at least one first monomer being a silicon-containing monomer and the at least one second monomer being essentially free of silicon, the at least on first monomer has a structure of formula (1):

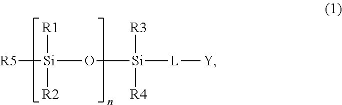

wherein: R1, R2, R3, and R4 are independently selected from —O—Si(CH₃)₃, alkyl, aryl, or alkylaryl; L is C₁-C₆-alkyl, or aryl, or alkylaryl; R5 is -L-Y, or Y, or —O—Si(CH₃)₃, or alkyl, or aryl, or alkylaryl; Y is acrylate, or methacrylate, or vinyl; n is 0-4; an amount of silicon is at least 5 wt % and not greater than 14 wt % based on the total weight of the polymerizable material, and the at least one second monomer comprises at least one multi-functional monomer, wherein in an amount of at least one multi-functional monomer of the second monomer is at least 30 wt % based on the total weight of the polymerizable material; bringing the photocurable composition into contact with a template;
irradiating the photocurable composition with light to form a photo-cured patterned layer; and removing the template from the patterned layer.

### BRIEF DESCRIPTION OF THE DRAWINGS

Embodiments are illustrated by way of example and are not limited in the accompanying FIGURE.

FIG. 1 includes a line drawing illustrating an imprint lithography template according to one embodiment.

### DETAILED DESCRIPTION

The following description is provided to assist in understanding the teachings disclosed herein and will focus on specific implementations and embodiments of the teachings. This focus is provided to assist in describing the teachings and should not be interpreted as a limitation on the scope or applicability of the teachings.

Unless otherwise defined, all technical and scientific terms used herein have the same meaning as commonly understood by one of ordinary skill in the art to which this invention belongs. The materials, methods, and examples are illustrative only and not intended to be limiting. To the extent not described herein, many details regarding specific materials and processing acts are conventional and may be found in textbooks and other sources within the imprint and lithography arts.

As used herein, the terms “comprises,” “comprising,” “includes,” “including,” “has,” “having” or any other variation thereof, are intended to cover a non-exclusive inclusion. For example, a process, method, article, or apparatus that comprises a list of features is not necessarily limited only to those features but may include other features not expressly listed or inherent to such process, method, article, or apparatus.

As used herein, and unless expressly stated to the contrary, “or” refers to an inclusive-or and not to an exclusive-or. For example, a condition A or B is satisfied by any one of the following: A is true (or present) and B is false (or not present), A is false (or not present) and B is true (or present), and both A and B are true (or present).

Also, the use of “a” or “an” are employed to describe elements and components described herein. This is done merely for convenience and to give a general sense of the scope of the invention. This description should be read to include one or at least one and the singular also includes the plural unless it is obvious that it is meant otherwise.

In one embodiment, the present disclosure is directed to a photocurable composition comprising a polymerizable material and at least one photoinitiator, wherein the polymerizable material comprises at least one first monomer and at least one second monomer. The at least one first monomer can include a silicon-containing monomer and the at least one second monomer can be essentially free of silicon. The at least on first monomer can have a structure of formula (1):

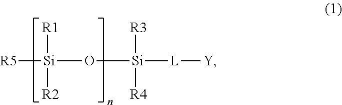

wherein
R1, R2, R3, and R4 are independently selected from —O—Si(CH₃)₃, alkyl, aryl, or alkylaryl; L is C₁-C₆-alkyl, or aryl, or alkylaryl; R5 is -L-Y, or Y, or —O—Si(CH₃)₃, or alkyl, or aryl, or alkylaryl; Y is acrylate, or methacrylate, or vinyl; and n is 0-4. The amount of silicon in the photocurable composition can be at least 5 wt % and not greater than 14 wt % based on the total weight of the polymerizable material; and the at least one second monomer may comprise at least one multi-functional monomer, wherein in an amount of at least one multi-functional monomer of the second monomer can be at least 30 wt % based on the total weight of the polymerizable material.

In a particular aspect of the structure of formula (1), R1, R2, R3, and R4 are independently selected from O—Si(CH₃)₃, or C₁-C₃ alkyl; L is C₁-C₅ alkyl or C₁-C₄-benzyl; Y is acrylate or methacrylate; and R5 is L-Y, or Y, or —O—Si(CH₃)₃, or C₁-C₃ alkyl; and n is 0 or 1.

The photocurable composition of the present disclosure can be designed for the fabrication of a bound soft mold with fine pattern. As used herein, the term “bound soft mold” refers to a new type of mask fabrication, also called a quartz-polymer-stack, which contains a quartz blank as supporting layer, herein also called “backing layer,” and a bonded polymeric layer on top of the quartz support, wherein the polymeric layer can comprise a certain pattern in order to function as a template for nanoimprint lithography (NIL) processing, herein also called “patterned layer.” The pattern in the polymeric layer of the bound soft mold can be made by patterning using a nanoimprint method.

The photocurable composition of the present disclosure can be suitable for the manufacturing of bound soft molds by forming patterned polymeric layers having a sub-10 nm resolution, and thereby may replace expensive quartz templates. In order to achieve this, the photocurable composition can combine the following parameters: being ink-jettable, which means having a low viscosity and good spreading behavior; a good release performance during the mold fabrication and pattern transfer; and mechanical strength properties after curing, such as a high reduced modulus, hardness, and flexibility, such that the mold can withstand at least 400 imprinting cycles.

As used herein, if not indicated otherwise, the expression “silicon-containing monomer” refers to a monomer falling under the structure of formula (1).

In one aspect of the photocurable composition, the amount of silicon can be at least 7 wt % based on the total weight of the polymerizable material, such as at least 10 wt %, at least 12 wt %, or at least 13 wt %. In other aspects, the amount of silicon in the photocurable composition may be not greater than 15 wt %, or not greater than 14 wt %, or not greater than 13 wt %, or not greater than 12 wt %, or not greater than 10 wt % based on the total weight of the polymerizable material.

In certain aspects, the molecular weight of the silicon-containing monomer can be at least 250 g/mol, or at least 300 g/mol, or at least 400 g/mol. In other aspects, the molecular weight of the silicon-containing monomer may be not greater than 800 g/mol, or not greater than 700 g/mol, or not greater than 600 g/mol, or not greater than 500 g/mol.

In a further aspect, the amount of the at least one silicon-containing monomer can be at least 20 wt % based on the total weight of the polymerizable material, such as at least 30 wt %, or at least 40 wt %, or at least 45 wt %, or at least 50 wt %, or at least 55 wt %, or at least 60 wt %. In another aspect, the amount of the silicon-containing monomer may be not greater than 70 wt % based on the total weight of the polymerizable material, or not greater than 65 wt %, or not greater than 60 wt %, or not greater than 55 wt %, or not greater than 50 wt %. In a particular aspect the amount of the silicon-containing monomer can be at least 30 wt % and not greater than 55 wt % based on the total weight of the polymerizable material.

Non-limiting example structures of polymerizable monomers falling under the structure of formula (1) of the silicon-containing monomer can be:

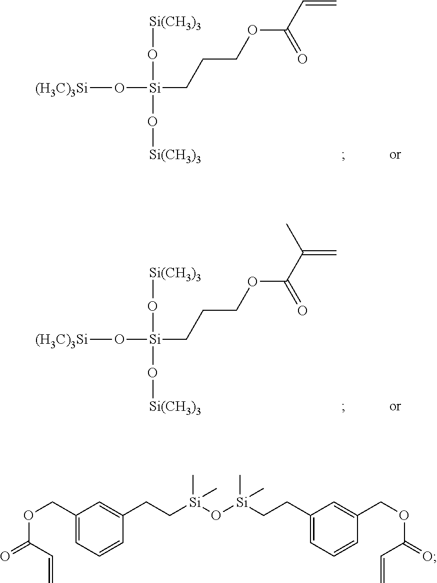

or any combination thereof.

The silicon-containing monomer of the polymerizable material of the photocurable composition can comprise at least one acrylate group, at least one vinyl group, or a combination thereof. In a particular embodiment, the silicon-containing monomer can comprise one acrylate group or two acrylate groups.

As used herein, the term acrylate group means unsubstituted or substituted acrylate groups, for example, it includes acrylate groups containing an alkyl substitution, such as a methacrylate group.

In one aspect, the vapor pressure at 25° C. of the silicon-containing monomer of the polymerizable material can be not greater than 0.01 Torr at standard ambient temperature and pressure (SATP), such as not greater than 0.005 Torr, or not greater than 0.002 Torr. In another aspect, the vapor pressure of the first monomer may be at least 0.0001 Torr or at least 0.001 Torr, or at least 0.005 Torr, or at least 0.008 Torr.

In a particular embodiment, the molecular weight of the silicon-containing monomer may be not greater than 800 g/mol, or not greater than 600 g/mol, or not greater than 500 g/mol, or not greater than 400 g/mol. In another aspect, the molecular weight of the first monomer can be at least at least 250 g/mol, or at least 300 g/mol, or at least 350 g/mol.

The second monomer of the polymerizable material of the photocurable composition can be essentially free of silicon. As used herein, essentially free of silicon means that the polymerizable material contains silicon in an amount of not greater than 1 wt % based on the total weight of the polymerizable material, or not greater than 0.5 wt %, or not greater than 0.1 wt %, or being free of silicon except for unavoidable impurities.

In one embodiment, the second monomer can comprise a multi-functional acrylate monomer. In a particular aspect, the second monomer can be a di-functional acrylate monomer, or a three-functional acrylate monomer, or a combination thereof. In a certain particular aspect, the second monomer can be a three-functional acrylate monomer.

Non-limiting examples of structures suitable for the second monomer can be, e.g.,

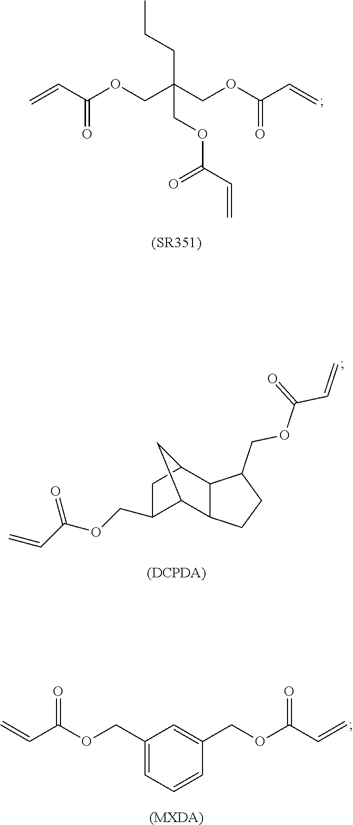

or any combination thereof.

The amount of polymerizable material of the photocurable composition can be at least 50 wt % based on the total weight of the photocurable composition, such as at least 60 wt %, at least 70 wt %, at least 80 wt %, at least 85 wt %, at least 90 wt %, or at least 94 wt %. In another aspect, the amount of polymerizable material may be not greater than 99 wt %, such as not greater than 98 wt %, or not greater than 96 wt %, or not greater than 94 wt %, or not greater than 90 wt % based on the total weight of the photocurable composition. The amount of polymerizable material can be a value between any of the minimum and maximum values noted above. In a particular aspect, the amount of the polymerizable material can be at least 80 wt % and not greater than 94 wt %.

In a particular aspect, the polymerizable material can consist essentially of the first monomer and the second monomer, wherein the first monomer may be a di-functional silicon-containing monomer and the second monomer may be a three-functional acrylate monomer (not containing silicon), the amount of silicon in the polymerizable material can be at least 10 wt % and not greater than 14 wt %, and a weight-percent ratio between the first monomer and the second monomer can range from 2.5:1 to 1:4.

In one aspect, the viscosity of the photocurable composition of the present disclosure can be not greater than 50 mPa·s, such as not greater than 40 mPa·s, not greater than 30 mPa·s, not greater than 25 mPa·s, not greater than 20 mPa·s. In other certain embodiments, the viscosity may be at least 2 mPa·s. or at least 3 mPa·s, or at least 5 mPa·s. As used herein, all viscosity values relate to viscosities measured at a temperature of 23° C. with the Brookfield method using a Brookfield Viscometer.

In one embodiment, the photocurable composition of the present disclosure can be essentially free of a solvent.

As used herein, if not indicated otherwise, the term solvent relates to a compound which can dissolve or disperse the polymerizable monomers and hindered stabilizer but does not itself polymerize during the photo-curing of the photocurable composition. The term “essentially free of a solvent” means herein an amount of solvent being not greater than 5 wt % based on the total weight of the photocurable composition. In a certain particular aspect, the amount of the solvent can be not greater than 3 wt %, not greater than 2 wt %, not greater than 1 wt %, or the photocurable composition can be free of a solvent, except for unavoidable impurities.

In order to initiate the photo-curing of the composition if exposed to light, one or more photoinitiators can be included in the photocurable composition.

In a certain aspect, the curing can also be conducted by a combination of light and heat curing.

The photocurable composition can further contain one or more optional additives. Non-limiting examples of optional additives can be stabilizers, dispersants, solvents, surfactants, inhibitors, or any combination thereof.

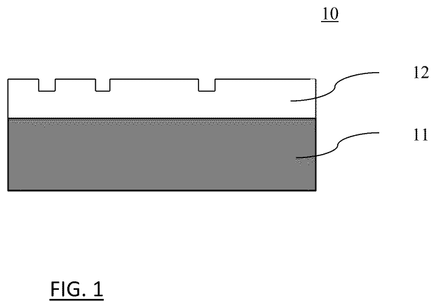

In another embodiment, as shown in FIG. 1, the present disclosure is directed to an imprint lithography template (10), comprising a backing layer (11) and a patterned layer (12). The imprint lithography template can further contain an adhesion layer (not shown) directly overlying the backing layer (11), which can improve binding of the patterned layer (12) to the backing layer (11). In one aspect, the patterned layer can be formed by curing the above-described photocurable composition of the present disclosure.

In one aspect of the imprint lithography template, a material of the backing layer can be quartz or silica.

In another aspect of the imprint lithography template (10), a water contact angle of the patterned layer (12) may be at least 70°, or at least 75°, or at least 80°, or at least 85°, or at least 90°. In another aspect, the water contact angle may be and not greater than 110°, or not greater than 105°, or not greater than 100°.

The patterned layer (12) can have a suitable mechanical strength to withstand a plurality of imprinting cycles without quality loss of the imprinting. In one aspect, the imprint lithography template of the present disclosure can be repeatedly used for imprinting at least 100 times, or at least 200 times, or at least 400 times, or at least 800 times, or at least 1000 times.

In a particular aspect, the material of the patterned layer may have a reduced modulus of at least 0.5 GPa, or at least 0.8 GPa, or at least 1.0 GPa, or at least 1.3 GPa, or at least 1.5 GPa, or at least 2 GPa, or at least 5 GPa. In another aspect, the reduced modulus may be not greater than 10 GPa, or not grater than 7 GPa, or not greater than 5 GPa, or not greater than 3 GPa, or not greater than 2 GPa, or not greater than 1.7 GPa, or not greater than 1.0 GPa. In a certain particular aspect, the reduced modulus can be at least 0.5 GPa and not greater than 2 GPa.

In a further particular aspect, a material of the patterned layer (12) can have a hardness of at least 0.05 GPa, or at least 0.10 GPa, or at least 0.12 GPa, or at least 0.15 GPa, or at least 0.2 GPa, or at least 0.25 GPa, or at least 0.30 GPa, or at least 0.35 GPa. In another aspect, the hardness may be not greater than 3 GPa, or not greater than 2 GPa, or not greater than 1.5 GPa, or not greater than 1.0 GPa, or not greater than 0.5 GPa, or not greater than 0.3 GPa, or not greater than 0.2 GPa.

In yet a further aspect, the surface free energy (SFE) of the patterned layer (12) may be not greater than 45 mJ/m², or not greater than 42 mJ/m², or not greater than 40 mJ/m², or not greater than 38 mJ/m², or not greater than 35 mJ/m². In another aspect the SFE may be at least 10 mJ/m², or at least 15 mJ/m², or at least 20 mJ/m².

In another aspect, the glass transition temperature (T_{g}) of the material of the patterned layer (12) can be at least 75° C., or at least 80° C., or at least 90° C., or at least 100° C., or at least 120° C., or at least 150° C. In a further aspect, the T_{g} may be not greater than 210° C., or not greater than 190° C., or not greater than 170° C., or not greater than 140° C., or not greater than 130° C., or not greater than 120° C. In a particular aspect the glass transition temperature can be at least 80° C. and not greater than 140° C.

The present disclosure is further directed to a method of forming the above-described imprint lithography template. The method can comprise applying a layer of the photocurable composition described above over a substrate (herein also called backing layer), bringing the photocurable composition into contact with a template (mother template); irradiating the photocurable composition with light to form a photo-cured patterned layer; and removing the template from the photo-cured patterned layer.

As further demonstrated in the examples, it has been surprisingly observed that photocurable compositions containing certain types and combinations of silicone-containing monomers and multi-functional acrylate monomers can have advantages for forming high quality patterned layers suitable for use as soft bond mold in nanoimprint lithography processes.

### EXAMPLES

The following non-limiting examples illustrate the concepts as described herein.

### Example 1

A series of photocurable compositions was prepared by using as polymerizable material silicon-containing monomers falling under structure of formula (1) in combination with multi-functional acrylate monomers not containing silicon. The silicon-containing monomers used for making the photocurable compositions were: 3-acryloxypropyltris(trimethylsiloxy)silane (MSi1); 3-methacryloxypropyltris(trimethylsiloxy)silane (MSi2); and 1,3-bis[(acryloxy methyl) phenethyl]tetramethyldisiloxane (MSi3). The silicon-containing monomers used for making the photocurable compositions are further summarized in Table 1. Table 1 further contains comparative silicon-containing monomers which are considered as not suitable for the photocurable compositions of the present disclosure (see CM1 to CM4).

As multi-functional polymerizable acrylate monomers not containing silicon (herein also called the at least one second monomer) were used m-xylyene diacrylate (MXDA), dihydrodicyclopentadienyl diacrylate (DCPDA), and trimethylol propane triacrylate (SR351A).

All photocurable compositions further contained 3 parts by weight of the fluorine-free surfactant SA3070 and 3 parts by weight of the photoinitiator Irgacure 651, such that the total weight of the polymerizable material, surfactant and photoinitiator together was 106 weight parts in each composition.

TABLE 1

| | | Vapor Pressure | |
|---|---|---|---|
| | Structure | at 25° C. [Torr] | Mw [g/mol] |
| MSi1 | 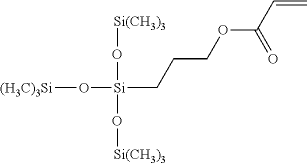 | 1.10 × 10⁻⁶ | 408 |
| MSi2 | 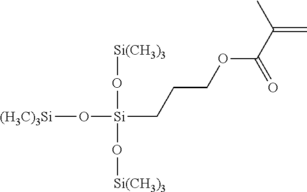 | 1.34 × 10⁻¹¹ | 683 |
| MSi3 | 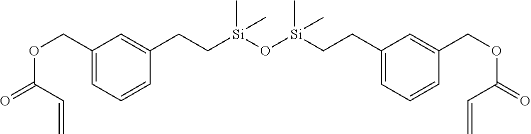 [SMILES: C=CC(=O)OCc1cccc(CC[Si](C)(C)O[Si](C)(C)CCc2cccc(COC(=O)C=C)c2)c1] | 1.52 × 10⁻¹¹ | 511 |
| CM1 | 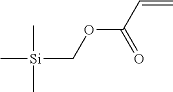 | 2.22 | 158 |
| CM2 | 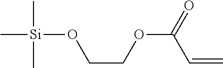 | 0.437 | 188 |
| CM3 | 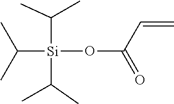 | 0.0649 | 228 |
| CM4 | 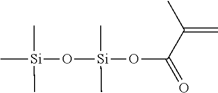 | 0.612 | 232 |

The investigated photocurable compositions are summarized in Table 2. The photocurable compositions representative to the present invention are compositions S1, S2, and S3, while photocurable compositions C1 to C5 are comparative compositions.

TABLE 2

| | S1 | S2 | S3 | C1 | C2 | C3 | C4 | C5 |
|---|---|---|---|---|---|---|---|---|
| MSi1 | 50 | 50 | 50 | 50 | 50 | 50 | 50 | 75 |
| MSi2 | | | | 50 | | | 30 | |
| MSi3 | | | | | 50 | | | |
| MSi4 | | | | | | 50 | | |
| MXDA | | | 50 | | | | | |
| DCPDA | | 50 | | | | | | 25 |
| SR351A | 50 | | | | | | 20 | |
| Si-content [%] | 12.92 | 12.92 | 12.92 | 24.52 | 18.10 | 22.60 | 19.88 | 19.39 |

### Viscosity of Photocurable Compositions

The viscosities were measured with a Brookfield DV-11+Pro viscometer using spindle #18. For each viscosity measurement, a sample of 6-7 ml was taken, added to the sample chamber and allowed to equilibrate for 15-20 minutes to reach the target temperature of 23° C. The viscosities were measured with spindle #18 at a speed of 135 rpm. For each sample, the measurement was three times repeated and an average value calculated.

For all tested photocurable compositions, the measured viscosities were in the range of 5 to 30 mPa·s at 23° C.

### Reduced Modulus and Hardness

The reduced modulus (herein also called just “modulus”) and the hardness of the photocurable compositions after photo-curing were tested by nanoindentation using a Hysitron TI 950 Triboindenter, which contained software named TriboScan to conduct the data analysis by relying on an integrated Oliver-Pharr method.

The photo-curing was conducted by adding 3 drops (each drop having a drop volume of 2 μl) of the photocurable composition to be tested on an adhesion-layer coated silicon wafer (Si-wafer) over an area of 25 mm×65 mm and covering the liquid with a flat quartz mask of 25 mm×75 mm to let it spread. The liquid film was radiated with UV light having a wavelength of 365 nm and a UV intensity of 2 J/cm². After the photo-curing the quartz mask was removed, wherein the photo-cured solid film remaining on the Si wafer had a thickness of about 3 microns.

Thereafter, the wafer with the photo-cured film was placed onto the stage of the Triboindenter. A diamond indenter (90 degrees corner tip) was used for conducting the indentation, which was calibrated by a standard fused silica. The reduced modulus Er in GPa was determined by measuring the load P and the displacement h (indentation depth). The indented depth was around 200 nm, and a 5×5 array of points was used to determine an average reduced modulus Er. During indentation, the force was measured from which the loading curves could be obtained. The hardness (H) was calculated according to the following equation: H=Pₘₐₓ/A_{c}, wherein Pₘₐₓ is the maximum applied force, and A_{c} is the contact area determined by the tip area function.

A summary of the test results is shown in Table 3.

TABLE 3

| Sample | S1 | S2 | S3 | C1 | C2 |
|---|---|---|---|---|---|
| Modulus [GPa] | 1.21 | 1.5 | 1.06 | 0.0031 | 0.0367 |
| Hardness [GPa] | 0.193 | 0.143 | 0.115 | 0.0009 | 0.0129 |
| Contact length [nm] | 165.9 | 179 | 177.9 | 168.8 | 143.7 |

It can be seen that the photo-cured layers of samples S1, S2, and S3 had a much higher hardness and modulus in comparison to samples C1 and C2. Not being bound to theory, it is assumed that a factor for the desired modulus and hardness may be a certain balance of silicon-containing monomer and muti-functional acrylate monomer, wherein the total amount of silicon in the polymerizable material is not greater than 14 wt %.

### Water Contact Angle of Photo-Cured Layers

The water contact angles to the solid layers obtained after photo-curing of samples S1 to S3 and comparative samples C1 and C2 were measured in order to evaluate the hydrophobic character of the surfaces, wherein the water contact angle increases with an increase in the hydrophobic character of a surface.

For measuring the water contact angles, photo-cured layers were prepared on fused silica glass slides coated with an adhesion layer to mimic the soft mold. The adhesion layer was prepared by spin coating a mixture of EA7140 (a phenolic methacrylate) from Shin-Nakamura Chemical, and T2059 (a triazine) from Tokyo Chemical Industry, in propylene glycol methyl ether acetate (PGMEA) solution, called herein EAT adhesion layer or EAT-coated fused silica glass slide. The EAT adhesion layer had a thickness of about 5 nm.

The photo-cured layers were made by adding to the EAT-coated fused silica glass slide three drops of 3.5 μl of the photocurable composition set 2 cm apart of each other. A clean quartz slide having a size of 25 mm×75 mm×1 mm was placed on top of the drops and the liquid photocurable composition allowed to fill the entire area covered by the quartz slide. Thereafter, the photocurable composition was cured with UV light using a radiation energy of 2 J/cm². After the photo-curing, the top quartz slide was peeled off, and the exposed cured polymeric layer was used for measuring the water contact angle using a Drop master DM-701 contact angle meter (made by Kyowa Interface Science Co. Ltd., Japan). For each contact angle measurement, a water drop of 2 μl was added by the machine to the target surface. Drop images were continuously captured by a CCD camera from the time the water drop touched the target surface. The contact angle was automatically calculated by software associated with the Drop master DM-701 contact angle meter. The data shown in table 4 correspond to the water contact angle at a time of 3 seconds after touching the target surface.

TABLE 4

| Sample | S1 | S2 | S3 | C1 | C2 |
|---|---|---|---|---|---|
| Water Contact | 100.2 | 97.6 | 80.5 | 64.5 | 54.3 |
| Angle [°] | | | | | |

It can be seen that high water contact angles (H₂O CA) to the photo-cured layers of compositions S1, S2, and S3 were obtained within a range of 80°-101°. In contrast, comparative samples C1 and C2, which had a silicone content of about 24.5 wt % and 18.1 wt %, respectively, had much lower contact angles of 64.5° and 54.3°, respectively.

### Glass Transition Temperature

In order to use the mold for imprinting at room temperature, the material of the mold should have a glass transition temperature or at least 50° C. to avoid deformation due to temperature.

The glass transition temperature was measured by rheometry, using an Anton-Paar MCR-301 rheometer coupled with a Hamamatsu Lightningcure LC8 UV source. The sample was radiated with a UV intensity of 1.00 mW/cm² at 365 nm measured by a Hamamatsu 365 nm UV power meter. Software named RheoPlus was used to control the rheometer and to conduct the data analysis. The temperature was controlled by a Julabo F25-ME water unit and set to 23° C. as starting temperature. For each sample testing, 7 μl test sample was added onto a plate positioned directly underneath the measuring system of the rheometer. Before starting with the UV radiation, the distance between glass plate and measuring unit was reduced to a gap of 0.1 mm. The UV radiation exposure was continued until the storage modulus reached a plateau, and the height of the plateau was recorded as the storage modulus.

After the UV curing was completed, the temperature of the cured sample was increased by controlled heating to measure the change of the storage modulus and loss modulus in dependency to the temperature to obtain the glass transition temperature T_{g}. As glass transition temperature T_{g} was considered the temperature corresponding to the maximal value of Tangent (θ), which is the ratio of storage modulus over loss modulus.

The glass transition temperature (T_{g}) measured after curing for samples S1, S2, and S3, and for comparative compositions C1, C2, and C5 can be seen in Table 6. The data show that the photocurable compositions representative for the present disclosure (samples S1, S2, and S3) formed after photo-curing solid polymeric materials having a T_{g} of greater than 90° C. In contrast, the glass transition temperature for comparative compositions C1, C2, and C5 was much lower, between 25° C. and 72° C.

TABLE 5

| Sample | Tg [° C.] |
|---|---|
| S1 | 118 |
| S2 | 134 |
| S3 | 97 |
| C1 | 48 |
| C2 | 25 |
| C5 | 72 |

The specification and illustrations of the embodiments described herein are intended to provide a general understanding of the structure of the various embodiments. The specification and illustrations are not intended to serve as an exhaustive and comprehensive description of all of the elements and features of apparatus and systems that use the structures or methods described herein. Separate embodiments may also be provided in combination in a single embodiment, and conversely, various features that are, for brevity, described in the context of a single embodiment, may also be provided separately or in any subcombination. Further, reference to values stated in ranges includes each and every value within that range. Many other embodiments may be apparent to skilled artisans only after reading this specification. Other embodiments may be used and derived from the disclosure, such that a structural substitution, logical substitution, or another change may be made without departing from the scope of the disclosure. Accordingly, the disclosure is to be regarded as illustrative rather than restrictive.

What is claimed is:

1. A photocurable composition comprising a polymerizable material and at least one photoinitiator, wherein
the polymerizable material comprises at least one first monomer and at least one second monomer, the at least one first monomer being a silicon-containing monomer and the at least one second monomer being essentially free of silicon;
the at least on first monomer has a structure of formula (1): 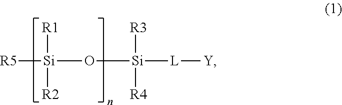
wherein: R1, R2, R3, and R4 are independently selected from —O—Si(CH₃)₃, alkyl, aryl, or alkylaryl;
L is C₁-C₅-alkyl, or aryl, or alkylaryl;
R5 is -L-Y, or Y, or —O—Si(CH₃)₃, or alkyl, or aryl, or
alkylaryl;
Y is acrylate, or methacrylate, or vinyl;
n: 0-4;
an amount of silicon is at least 5 wt % and not greater than 14 wt % based on the total weight of the polymerizable material; and
the at least one second monomer comprises at least one multi-functional monomer, wherein in an amount of at least one multi-functional monomer of the second monomer is at least 30 wt % based on the total weight of the polymerizable material.

2. The photocurable composition of claim 1, wherein an amount of the polymerizable material is at least 80 wt % based on the total weight of the photocurable composition.

3. The photocurable composition of claim 1, wherein the silicon-containing monomer comprises at least one acrylate group.

4. The photocurable composition of claim 1, wherein an amount of the silicon-containing monomer is at least 25 wt % based on the total weight of the polymerizable material.

5. The photocurable composition of claim 3, wherein an amount of silicon-containing monomer is at least 40 wt % based on the total weight of the polymerizable material.

6. The photocurable composition of claim 1, wherein the silicon-containing monomer has a structure selected from: 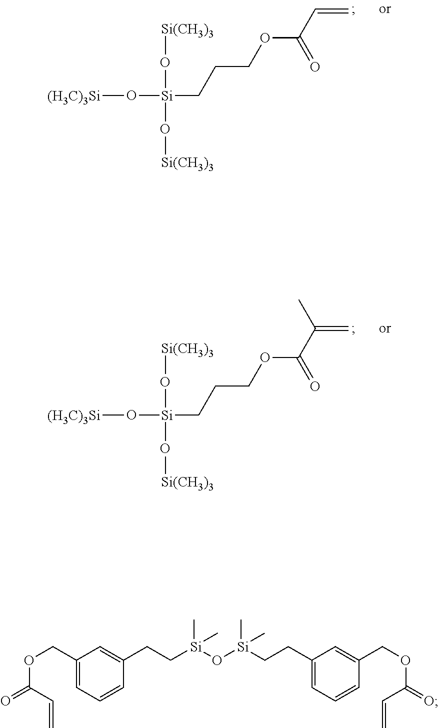
or any combination thereof.

7. The photocurable composition of claim 1, wherein the amount of the multi-functional monomer is at least 45 wt % based on the total weight of the polymerizable material.

8. The photocurable composition of claim 1, wherein the at least one second monomer includes a di-functional acrylate monomer, a tri-functional acrylate monomer, or a combination thereof.

9. The photocurable composition of claim 8, wherein the at least one second monomer includes trimethylolpropane triacrylate, tricyclodecane dimethanol diacrylate, meta-xylene diacrylate, or any combination thereof.

10. The photocurable composition of claim 8, wherein the at least one second monomer consists essentially of a tri-functional acrylate monomer.

11. The photocurable composition of claim 1, wherein the polymerizable material consists essentially of the at least one first monomer and the at least one second monomer, the at least one second monomer being a multi-functional acrylate monomer, and a weight-percent ratio between the at least one first monomer to the at least one second monomer ranges from 2.5:1 to 1:4.

12. The photocurable composition of claim 1, wherein the photocurable composition is essentially free of fluorine.

13. The photocurable composition of claim 1, wherein a viscosity of the photocurable composition at a temperature of 25° C. is not greater than 30 mPa·s.

14. The photocurable composition of claim 1, wherein a molecular weight of the silicon containing monomer is at least 200 g/mol and not greater than 800 g/mol.

15. The photocurable composition of claim 1, wherein a vapor pressure of the silicon containing monomer at 25° C. is not greater 0.01 Torr.

16. An imprint lithography template comprising a backing layer and a patterned layer overlying the backing layer, wherein the patterned layer is formed from the photocurable composition of claim 1.

17. The imprint lithography template of claim 16, wherein the patterned layer has a reduced modulus of at least 1 GPa.

18. The imprint lithography template of claim 16, wherein the patterned layer has a hardness of at least 0.1 GPa.

19. The imprint lithography template of claim 16, wherein a water contact angle of the patterned layer is at least 70°.

20. A method of forming an imprint lithography template, comprising:
applying a layer of a photocurable composition on a backing layer, wherein the photocurable composition comprises a polymerizable material and at least one photoinitiator, the polymerizable material comprises
at least one first monomer and at least one second monomer, the at least one first monomer being a silicon-containing monomer and the at least one second monomer being essentially free of silicon,
the at least on first monomer has a structure of formula (1): 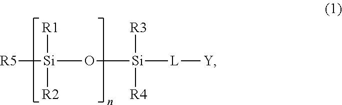
wherein: R1, R2, R3, and R4 are independently selected from —O—Si(CH₃)₃, alkyl, aryl, or alkylaryl;
L is C₁-C₅-alkyl, or aryl, or alkylaryl;
R5 is -L-Y, or Y, or —O—Si(CH₃)₃, or alkyl, or aryl, or
alkylaryl;
Y is acrylate, or methacrylate, or vinyl;
n: 0-4;
an amount of silicon is at least 5 wt % and not greater than 14 wt % based on the total weight of the polymerizable material, and
the at least one second monomer comprises at least one multi-functional monomer, wherein in an amount of at least one multi-functional monomer of the second monomer is at least 30 wt % based on the total weight of the polymerizable material;
bringing the photocurable composition into contact with a template;
irradiating the photocurable composition with light to form a photo-cured patterned layer; and
removing the template from the patterned layer.
